(19) United States
(12) Patent Application Publication
(10) Pub. No.: US 2006/0027912 A1
(43) Pub. Date: Feb. 9, 2006

(54) Film carrier tape for mounting of electronic part

(76) Inventors: Tatsuo Kataoka, Ageo-shi, Saitama (JP); Hiroyuki Soutome, Shimonseki-shi, Yamaguchi (JP)

Correspondence Address: THE WEBB LAW FIRM, P.C., 700 KOPPERS BUILDING, 436 SEVENTH AVENUE, PITTSBURGH, PA, 15219, US

(21) Appl. No.: 10/534,401

(22) PCT Filed: Nov. 6, 2003
(86) PCT No.: PCT/JP03/14156

§ 371 Date: May 10, 2005

(30) Foreign Application Priority Data
Nov. 11, 2002 (JP) 2002-327052

(51) Int. Cl. H01L 23/053

(52) U.S. Cl. 257/701

(57) ABSTRACT

A film carrier tape for mounting electronic components includes comprises an insulating film and, on the surface thereof, an inner connection terminal, an outer connection terminal and wiring for connecting these terminals, and further includes a solder resist layer covered in such a way that the connection terminals are exposed, and the tape secures an electrical connection of a connection terminal of an electronic component and the inner connection terminal by applying an ultrasonic wave on the inner connection terminal in mounting the electronic component. The wiring positioned from a part where the inner connection terminal is electrically connected with the connection terminal of the electronic component to the edge of the solder resist layer and wiring in a 1000 μm length from the edge of the solder resist, which wiring is protected by the solder resist layer, are formed in an almost straight shape. The film carrier tape for mounting electronic components having the above structure does not receive any concentration of stress when an ultrasonic wave is applied and thereby cracks or disconnections in the wiring pattern are virtually eliminated.

### FIELD OF THE INVENTION

The present invention relates to a film carrier tape for mounting electronic components, which tape hardly causes cracks or disconnection on a wiring pattern formed on a film carrier in mounting electronic components on the film carrier by heating with an ultrasonic wave.

### BACKGROUND OF THE INVENTION

Known examples of a method for mounting electronic components (devices), such as semiconductor chips and the like on a film carrier may include a wire bonding method, TAB method, flip chip method (FC) and the like. These mounting methods mostly have such a procedure that an ultrasonic wave is applied on a wiring pattern formed on a film carrier under heating and thereby a connecting member and a connection terminal (bonding pat) of the wiring pattern are electrically connected in mounting an electronic component on a film carrier. Of these methods for mounting electronic components, for example, in the wire bonding method using a conductive metal fine wire such as a gold wire and the like, one end part of the conductive metal fine wire is connected with a bump electrode (device side electrode) formed on the electronic component, the other end part of this conductive metal fine wire is connected to a bonding pad which is an inner terminal of the film carrier and thereby the electronic component and the film carrier are electrically connected.

The wire bonding is described in detail with reference to the following drawings. As shown in FIG. 10, when a bump electrode 81 formed on an output terminal and a bonding pad 88 formed on a film carrier 89 are electrically connected using a gold wire 87 in an electronic component 80, the gold wire 87 is abutted to the bump electrode 81 and the bonding pad 88, an ultrasonic wave is applied with heating using a bonding tool (not shown), the gold wire 87 is fused and bonded to the bump electrode 81 and the bonding pad 88 and thereby the electronic component 80 is mounted on the film carrier 89.

The film carrier 89 in which the bonding pad 88 is formed is generally prepared in the following manner. On the surface of an insulating film 86 made of a polyimide film or the like, a conductive metal foil such as electrodeposited copper foil or the like is adhered, a photosensitive resin layer is formed with coating on the surface of the conductive metal foil and the photosensitive resin layer is developed by sensitizing on a desired pattern to form the desired pattern comprised of the photosensitive resin. Using the pattern as a masking material, the conductive metal foil is etched selectively and thereby a wiring pattern corresponding to the pattern comprised of the photosensitive resin is formed and a solder resist layer 85 is formed in such a way that the bonding pad 88 of the wiring pattern thus formed is exposed.

Conventionally, when the electronic component 80 is mounted on the film carrier 89 thus formed by wire bonding, the bump electrode 81 and the bonding pad 88 are electrically connected using the gold wire 87 with application of an ultrasonic wave under heating. In the film carrier in which the conductive metal foil for forming wiring is thick and a width of formed wiring is large, the bonding with an ultrasonic wave does not cause problems particularly.

However, recently, a film carrier having the almost same area as that of an electronic component for mounting such as Ball Grid Array (BGA) or Chip On Film (CSP) has been used in order to mount electronic components with high density. In such a film carrier, a very thin conductive metal foil is used and the wiring width for forming is fined.

Furthermore, in BGA or CSP, mounting electronic components is carried out by forming a solder resist layer with coating on the wiring pattern formed, adhering an electronic component on the solder resist layer with an adhesive or the like and wire bonding between the bonding pad exposed from the edge of the solder resist-layer and the bump electrode formed on the non-adhering part of the electronic component with a gold wire. Therefore, it is possible to use a relatively hard resin as a solder resist. On this account, the wiring pattern formed on the insulating film is firmly sandwiched and supported between the insulating film 86 and the solder resist layer 85 so that it has a low degree of freedom toward vibration or the like.

After the electronic component is mounted, in order to protect the wiring pattern from the outside stress, it is preferred to firmly sandwich and support the wiring pattern by the insulating film and the solder resist layer as described above. However, in mounting the electronic component with wire bonding, it is necessary to apply vibration on the wiring pattern with application of an ultrasonic wave on the bonding pad. If the wiring pattern is firmly sandwiched and supported by the solder resist layer and the insulating film, the vibration caused by an ultrasonic wave applied on the bonding pad directly influences the wiring pattern near the edge of the solder resist layer. Furthermore, the wiring pattern is formed from a thin conductive metal foil and the width thereof is narrow. Therefore, it induces new problems such that the probabilities of disconnection of the wiring pattern in the film carrier such as BGA, CSP and the like, occurrence of cracks in the wiring pattern, occurrence of cracks in the solder resist layer or other occurrences are markedly increased as compared with conventional film carriers.

Particularly, in order to increase a production efficiency, wire bonding is carried out with application of an ultrasonic wave having a high output power for a short time under heating to cause problems such that occurrence of cracks in the wiring pattern, occurrence of disconnection in the wiring pattern and occurrence of cracks in the solder resist are markedly increased. These effects induce very serious problems for the improvement of productivity, lowering of the production cost of film carriers and reliability of the film carrier provided with electronic components.

### DISCLOSURE OF THE INVENTION

It is an object of the invention to provide a film carrier tape for mounting electronic components which tape hardly induces cracks or disconnection in a wiring pattern by heating with an ultrasonic wave in wire bonding.

The film carrier tape for mounting electronic components according to the present invention has an inner connection terminal, an outer connection terminal and a wiring for connecting the connection terminals on the surface of an insulating film, and further has a solder resist layer provided with coating so as to expose the connection terminals, and in mounting an electronic component, the film carrier tape can perform electrical connection of the connection terminal of an electronic component and the inner connection terminal by application of an ultrasonic wave on the inner connection terminal. The film carrier tape for mounting electronic components according to the present invention is characterized in that the wiring is formed in an almost straight shape in the range of from the part where the inner connection terminal is electrically connected with the connection terminal of the electronic component to the edge of the solder resist layer, and in the range 1000 μm length from the edge of the solder resist layer which range is protected by the solder resist layer.

In the film carrier tape for mounting electronic components according to the present invention, the crystalline structure of a conductive metal for constituting wiring before securing electric connection with the electronic component is identical to the crystalline structure of the conductive metal for constituting wiring after securing electric connection with the electronic component. The film carrier tape for mounting electronic components is constructed so that the crystalline structure of the conductive metal is not substantially changed by an ultrasonic wave and heating applied for securing electric connection with the electronic component.

In the film carrier tape for mounting electronic components having the above constitution according to the present invention, an ultrasonic wave is applied with heating for securing electric connection with the electronic component. However, the film carrier tape for mounting electronic components according to the present invention has a structure such that the stress applied on the wiring pattern by an ultrasonic wave is hardly concentrated, so that disconnection of wiring or occurrence of cracks caused by stress concentration can be prevented and also occurrence of cracks in the solder resist can be effectively prevented.

### BRIEF DESCRIPTION OF DRAWING

FIG. 1 is a cross-section view showing one embodiment of a film carrier tape for mounting electronic components according to the present invention.

FIG. 2 is a perspective view showing a state of wire bonding on an inner connection terminal formed in a film carrier tape for mounting electronic components according to the present invention.

FIG. 3 is an enlarged plan view of the part of an inner connection terminal subjected to wire bonding.

FIG. 4 is an A-A cross-section view of FIG. 3.

FIG. 5 is a view showing a state of occurrence of cracks or disconnection in a wiring pattern neighborhood a bonding pad.

FIG. 6 is a view of showing a state of occurrence of cracks or disconnection in a wiring pattern neighborhood a bonding pad.

FIG. 7 is an electron microscope photograph showing a cross-section of a grain structure of an electrodeposited copper in the part where cracks or disconnection are caused.

FIG. 8 is an electron microscope photograph showing an embodiment of a grain structure in a cross-section of an electrodeposited copper.

FIG. 9 (a) and (b) are cross-sections showing other embodiments of a film carrier tape for mounting electronic components according to the present invention.

FIG. 10 is a cross-section showing a state of wire bonding in a conventional film carrier tape for mounting electronic components.

### BEST MODE FOR CARRYING OUT THE INVENTION

Hereinafter, the film carrier tape for mounting electronic components according to the present invention will be described in detail with reference to the following specific embodiments.

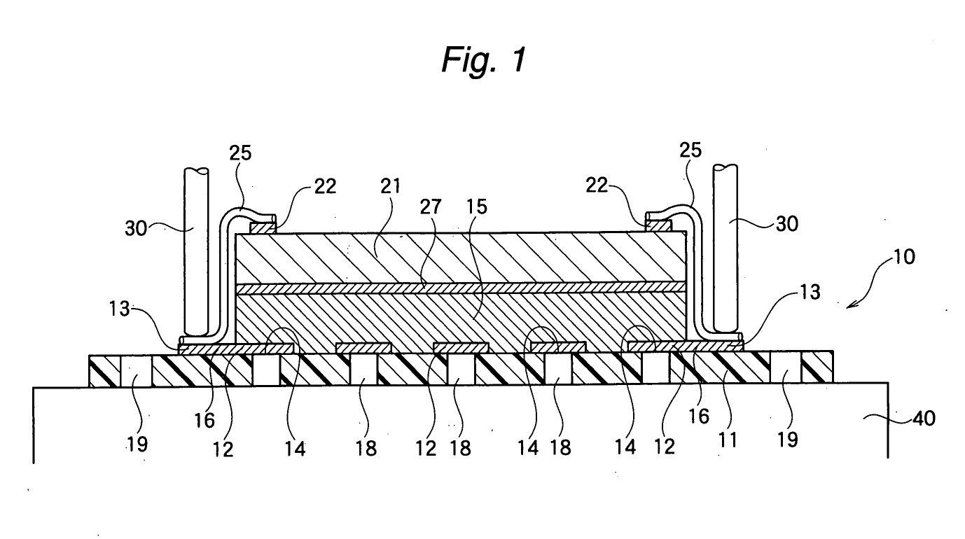

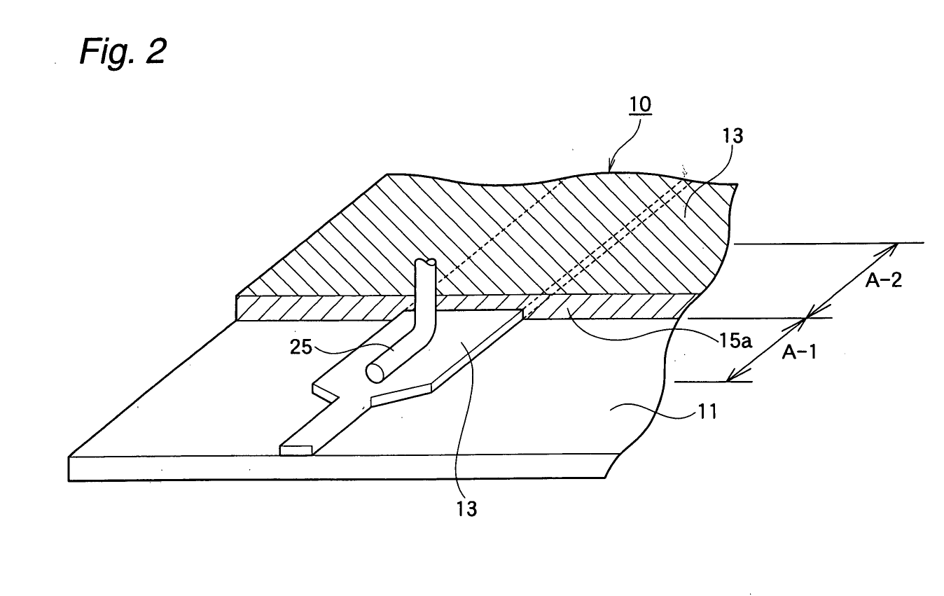

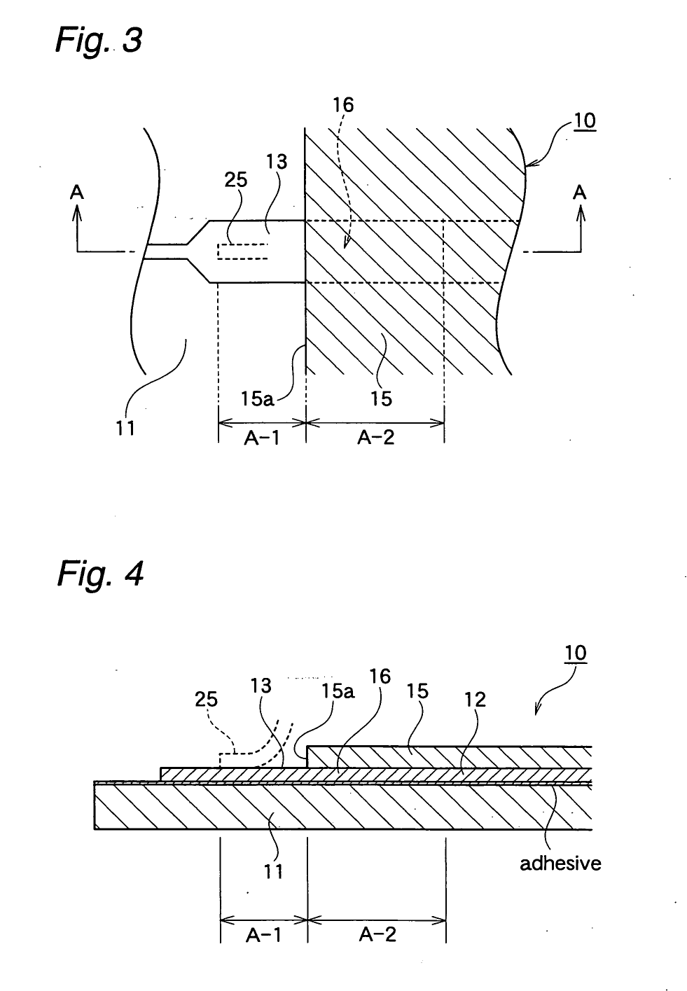

FIG. 1 is a cross-section view showing one embodiment of a film carrier tape for mounting electronic components according to the present invention, FIG. 2 is a perspective view showing a state of subjected to wire bonding on an inner connection terminal, FIG. 3 is an enlarged plan view of the part of an inner connection terminal subjected to wire bonding and FIG. 4 is an A-A cross-section view in FIG. 3.

The film carrier tape 10 for mounting the electronic components according to the present invention has an insulating film 11, wiring patterns 12 formed on at least one surface of this insulating film 11, and a solder resist layer 15 formed in such a way that an inner connection terminal 13 and an outer connection terminal 14 are exposed in the wiring pattern 12. The surfaces of the inner connection terminal 13 and the outer connection terminal 14 exposed from the solder resist layer 15 are usually treated with plating by tin, solder, gold, nickel-gold and the like, in accordance with the use. In the film carrier tapes for mounting electronic components as shown in FIGS. 1 to 4, an electronic component 21 is disposed on the surface of the solder resist layer 15 through an adhesive layer 27.

The film carrier tape 10 for mounting electronic components according to the present invention as shown in FIGS. 1 and 2 can be prepared by adhering a conductive metal foil on the surface of the insulating film 11, coating a photosensitive resin on the surface of the conductive metal foil, forming a desired pattern with exposure and development of the photosensitive resin, selectively etching the conductive metal foil by using the pattern as a masking material, and thereby forming a wiring pattern composed of the conductive metal.

The insulating film 11 for forming the film carrier tape 10 for mounting electronic components according to the present invention has chemical resistance in order that it is not subjected to erosion by chemicals because it will be contacted with acids and the like in etching and also has heat resistance such that it is not changed by heating in bonding. Examples of materials for forming the insulating film 11 may include polyesters, polyamides, polyimides and the like. Particularly, it is preferred in the present invention to use the film composed of polyimide. As compared with other resins, such polyimides have not only excellent heat resistance but also excellent chemical resistance.

Examples of the polyimide resin may include all aromatic polyimides synthesized by pyrromellitic dianhydride and aromatic diamine, and all aromatic polyimides having a biphenyl skeleton synthesized by biphenyl tetra carboxylic dianhydride and aromatic diamine. Particularly, it is preferred in the present invention to use all aromatic polyimides having a biphenyl skeleton (for example, Trade Name: UPILEX S, manufactured by Ube Industries Ltd.). All aromatic polyimides having a biphenyl skeleton have a water-absorption lower than those of other all aromatic polyimides. The insulating film 11 usable in the present invention has a thickness of usually from 25 to 125 μm, preferably 25 to 75 μm.

The insulating film 11 which forms the film carrier tape 10 for mounting electronic components according to the present invention is formed with sprocket holes (perforations) 19 on both of the ends thereof, and solder ball holes 18 in which ball pads are exposed. Further, in the film, slits, positioning holes and the like (not shown) may be formed.

In the present invention, it is possible to use a copper foil, aluminum foil and the like as the conductive metal foil. Suitably usable examples of the copper foil may include a rolled copper foil and an electrodeposited copper foil. Particularly, it is high effective to use the electrodeposited copper foil in the present invention.

In preparing the film carrier tape 10 for mounting electronic components, the thickness of the electrodeposited copper foil preferably used becomes thinner in accordance with the recent demand that electronic components are mounted with high density. The electrodeposited copper foil suitably used in the present invention has an average thickness of usually not more than 75 μm, preferably not more than 35 μm. When the copper foil having a thickness of not more than 35 μm is used in the film carrier tape for mounting electronic components according to the present invention, disconnection is hardly caused. The lower limit of the thickness of the electrodeposited copper foil is not particularly defined. However, the electrodeposited copper foil having an average thickness of less than 5 μm is difficultly prepared in an industrial production scale, and even if it is prepared, it is very difficult to handle the electrodeposited copper foil having such an average thickness as it is. Therefore, the lower limit of the average thickness of the electrodeposited copper foil effectively used in the present invention is 5 μm.

On the conductive metal foil, the photosensitive resin is coated and the photosensitive resin layer thus formed is exposed and developed to form a pattern made up of the photosensitive resin. Further, using the pattern as a masking material, the conductive metal foil is selectively etched to form the wiring pattern 12 made up of the conductive metal.

The wiring pattern 12 thus formed has the inner connection terminals 13 for securing electric connection with the electronic component 21 and the outer connection terminals 14. The inner connection terminals 13 and the outer connection terminals 14 are connected by the wirings 16 formed by selectively etching the conductive metal foil.

After the wiring pattern 12 is formed by selectively etching of the conductive metal foil, it is necessary to establish new electric connection using the inner connection terminals 13 for establishing electric connection with the electric component 21 and the outer connection terminals 14 for connecting with the outside by connecting with the inner connection terminals 13 through the wirings 16 and therefore these terminals are necessary to maintain in an exposed state. However, the wirings 16 which electrically connect the inner connection terminals 13 and the outer connection terminals 14 is protected by coating with a solder resist in order to prevent the wirings 16 from damage in production of film carriers, in mounting electric components, in transportation thereof or the like, or in order to secure electric insulation with adjacent wirings. In FIGS. 1 to 3, the number 15 shows the solder resist coated layer (namely, solder resist layer).

The solder resist layer 15 can be formed by, for example, applying the solder resist with a screen mask or the like and curing with heating, or by thermocompression bonding a resin piece having a predetermined shape pouched out for forming the solder resist.

The solder resist layer 15 is formed in the above manner so that the wiring pattern 12 is firmly sandwiched and supported between the solder resist layer 15 and the insulating film 11. As a result, the wiring pattern 12 hardly receives damage by physical stress from the outside.

When the solder resist layer 15 is formed in the above manner, the wiring pattern 12 can be effectively protected from external stress. However, the stress relaxation property to the stress caused in the wiring pattern inside is lowered because the solder resist layer 15 is formed, the protected part of the wiring pattern 12 is firmly fixed between the solder resist layer 15 and the insulating film 11.

In the film carrier tape 10 for mounting electronic components according to the present invention, in order to secure electric connection of the electronic component 21 with this film carrier, as shown in FIG. 1, one end part of the conductive metal thin wire such as gold wire 25 or the like is subjected to bonding with a bump electrode 22 formed on the electronic component 21 and also the other end is subjected to bonding with the bonding pad 13, which is an inner connection terminal of the wiring pattern 12, using a bonding tool 30.

The bonding tool 30 is used herein in such a way that a conductive metal thin wire 25 such as gold wire or the like is pressed onto the bonding pad (inner connection terminals) 13, and the conductive metal thin wire 25 is fused and bonded on the surface of the bonding pad 13 by application of an ultrasonic wave with heating. In the bonding, the temperature of a stage 40 for heating is usually about from 120 to 200° C., and the output of the ultrasonic wave is about from 0.5 to 1.0 W. The conductive metal thin wire 25 is fused and bonded on the bonding pad by an ultrasonic wave having such an output. For example, in using a thick electrodeposited copper foil having a thickness of over 75 μm, it has been not considered that the wiring pattern 12 itself including the bonding pad 13 is influenced by the ultrasonic wave caused from the bonding tool 30. However, in forming the wiring pattern 12, the thinner the thickness of the electrodeposited copper foil is, the higher the probability that cracks or disconnection are induced in the wiring pattern 12 is. The occurrence of cracks or disconnection in the wiring pattern 12 is caused with a definite pattern, but at random. That is, cracks or disconnection caused in the wiring pattern 12 occurs after the application of an ultrasonic wave under heating with the bonding tool 30. According to an examination on the crystal structure of the electrodeposited copper foil for forming the wiring pattern on the part where cracks or disconnection occurred, the crystal structure of the section of the part where the cracks or disconnection occurred is, compared with a part where cracks or disconnection did not occur, such a state that the crystal grains of the part where cracks or disconnection occurred are bulked up to a round state and the bulked round gain boundaries become a breaking point. The parts inducing such breakage are concentrated on the side of the solder resist layer 15 from the part on which an ultrasonic wave is applied as a basic point in the bonding pad 13, and in the under surface of the solder resist layer 15, the parts inducing breakage are concentrated on the range 1000 μm inwardly from the edge 15a of the solder resist layer 15. And such cracks or disconnection concentrically occur on the points where the shape of the wiring pattern 12 sharply changes.

In general, the electrodeposited copper foil used in forming wiring patterns has a fine and angular electrodeposition texture (cross-sectional grain structure). The texture of the electrodeposited copper foil is not changed after the formation of the wiring pattern. Further, the texture of the part where cracks or disconnection do not occur in the wiring pattern is not different from the texture of the electrodeposited copper foil used. When the crystal structure of the electrodeposited copper foil is identical in the wiring pattern before bonding and the wiring pattern after bonding, cracks and disconnection are not caused. Regarding to the electrodeposited copper foil, the crystal structure of the electrodeposited copper foil is not changed, for example, after heating at 300° C. for 1 hr. However, for example, when the electrodeposited copper foil is heated at 400° C. for 30 min, it is confirmed that similar to the part where cracks or disconnection are caused in the wiring pattern, the crystal grains of the electrodeposited copper are bulked and re-crystallized in a round state. However, the steps of forming the wiring pattern on the insulating film do not include a step of exposing the electrodeposited copper in the severe heating conditions as described above. Further it is confirmed that when an ultrasonic wave is applied under heating in order to secure connection with the electronic component, the heating temperature is lower than the temperature at which the above electrodeposited copper is re-crystallized, but the stress stronger than the stress corresponding to the thermal stress caused in heating the above electrodeposited copper foil at 400° C. for 30 min is concentrically applied on the wiring pattern locally.

That is, when an ultrasonic wave is applied on the inner connection terminals (bonding pads) 13 under heating in such a state that the one edge is firmly fixed on the insulating film 11 by the solder resist layer 15, the stress is concentrated on from the part on which an ultrasonic wave is applied in the bonding pad 13 to the direction of the solder resist layer 15. The stress caused by this ultrasonic wave is transmitted to the wiring pattern 12 sandwiched and supported between the solder resist layer 15 and the insulating film 11, and further influences on the wiring pattern 12 positioned in the range 1000 μm from the edge 15a of the solder resist layer 15. Particularly, as the wiring pattern 12 positioned in the range 1000 μm from the edge 15a of the solder resist layer 15 has high identity with the solder resist layer, when the influence caused by an ultrasonic wave appears in this part of the wiring pattern 12, it frequently exerts the solder resist layer which is united with the wiring pattern 12. Therefore, when cracks or disconnection occur in this part of the wiring pattern 12, troubles such as occurrence of cracks and the like are frequently observed in the solder resist layer 15 for protecting this part.

In the range over 1000 μm from the edge 15a of the solder resist layer 15, the wiring pattern 12 is firmly fixed by a firm holding force to the wiring pattern 12 with the solder resist layer 15 and the insulating film 11 and thereby the influence of the stress caused by an ultrasonic wave is rapidly decayed.

However, the bonding pad 13 which is the wiring pattern 12 extendedly set up outwardly from the solder resist layer 15, and the wiring 16 connected with the bonding pad 13 are formed in such a state that one end of each of the bonding pad 13 and the wiring 16 connected to the bonding pad 13 is firmly held like a cantilever by the solder resist layer 15 and the insulating film 11 so that the bonding pad 13 and the wiring 16 are easily influenced by an ultrasonic wave in bonding. Furthermore, because an ultrasonic wave is shield in the position about 1000 μm inwardly apart from the edge 15a of the solder resist layer, it is considered that in the side of the bonding pad 13 from the edge 15a, the ultrasonic waves applied and the reflected ultrasonic waves resound or interfere each other. It is further considered that when the ultrasonic waves amplified by the interference or resonance are concentrated on one point, they can become a stress capable of changing the texture of crystal grains of the electrodeposited copper.

Under the above circumstances, the present inventors studied on occurrence of cracks or disconnection in a wiring pattern in the following manner.

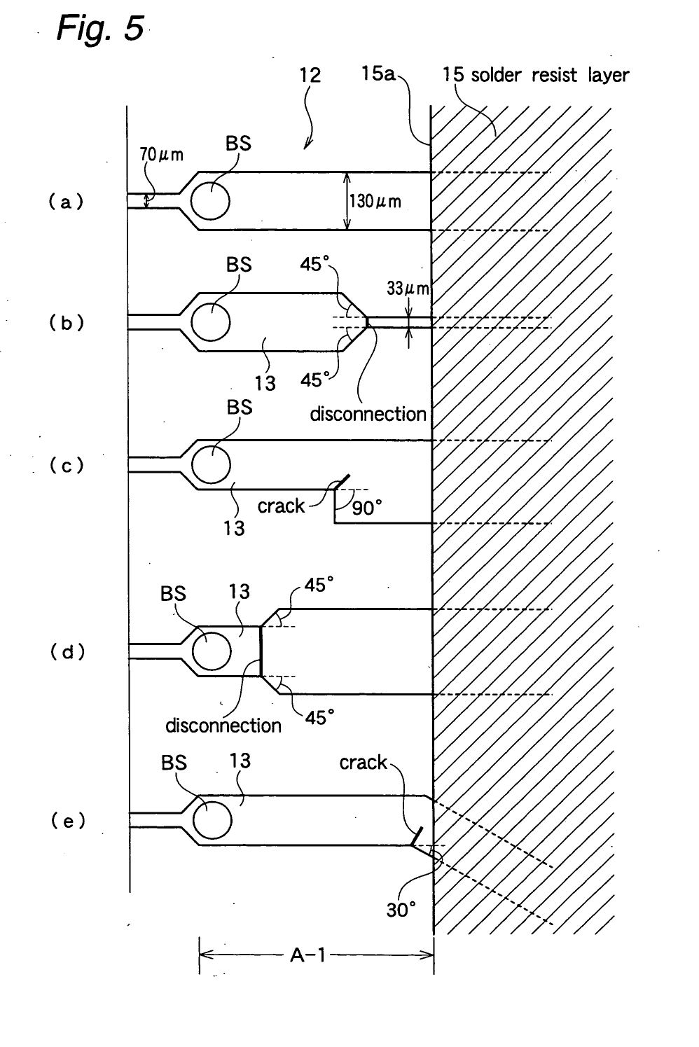

The present inventors formed wiring patters having shapes as shown in (a) to (e) in FIG. 5 using an electrodeposited copper foil having an average thickness of 18 μm. A solder resist was applied in such a way that an edge 15a was positioned in the part of 500 μm apart from the edge of an insulating film made up of a polyimide film having an average thickness of 50 μm and cured to form a solder resist layer 15. As shown each figure in FIG. 5, a bonding pad 13 was formed, an ultrasonic wave was applied on a bonding spot BS with heating and the occurrence of cracks or disconnection in the wiring pattern was examined. The apparatus used in the examination was a wire bonding apparatus manufactured by K&S Co., Ltd, the output of an ultrasonic wave was 3.1 W, and the heating temperature with the stage 40 for heating was 200° C. An ultrasonic wave was applied for 0.02 sec in these conditions and the presence or absence of cracks or disconnection was examined. This test is an accelerating test for confirming the conditions of occurred cracks or disconnection. The output of ultrasonic waves and the temperature are the maximum values in the apparatus used, and energy three times as much as the applied energy in general bonding is applied in the apparatus. The shape and the dimension of each bonding pad are shown in FIG. 5. The distance A-1 from the edge of the bonding spot BS to the edge 15a of the solder resist layer 15 is 500 μm.

As a result, in the wiring pattern shown in FIG. 5(a) in which the part positioned in the side of the solder resist 15 from the bonding spot BS is formed in a straight shape, cracks or disconnection were not occurred. To the contrary, in the wiring pattern in which the bonding pad 13 is connected to the narrowed wiring as shown in FIG. 5 (b), disconnection was occurred in the narrowed part. In the wiring pattern in which the bonding pad is connected to the wiring being turned and spread at an almost right angle in the width direction as shown in FIG. 5 (c), cracks were occurred in the part where the wiring is turned and spread at a right angle, namely, in the inflection point at which the wiring pattern is sharply changed. In the wiring being turned and spread at an angle of about 45 degree at the part it connects to the bonding pad 13 as shown in FIG. 5 (d), disconnection was occurred in the connection part. Furthermore, as shown in FIG. 5 (e), in the wiring pattern in which the wiring is connected to the bonding pad 13 and they have the same width, and the wiring is bended at an angle of about 30 degree short of the solder resist layer, at the bended point, namely the inflection point at which the wiring is changed sharply, a cracks was occurred.

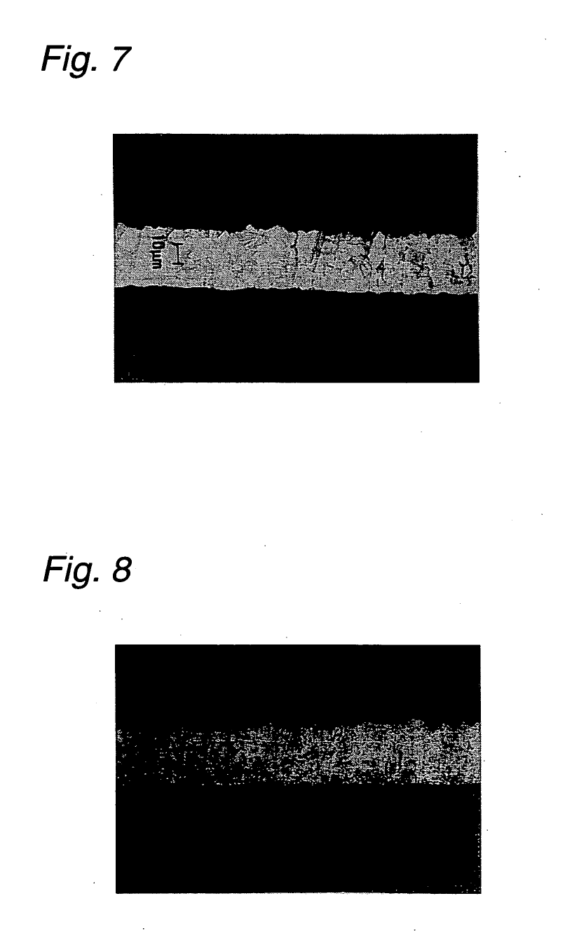

As described above, the wiring connected to the bonding pad 13 has an inflection point at which the wiring is sharply changed in the range of from the bonding spot SB to the solder resist layer, so that at this inflection point, disconnection or cracks is occurred. Furthermore, the cross-section of each part where disconnection or cracks were occurred is observed by an electron microscope. As shown in FIG. 7, the crystal grains of the electrodeposited copper were bulked and re-crystallized in a round state. The re-crystallized part was clearly different from the part where cracks or disconnection did not occur and the electron microscope photograph (FIG. 8) of the crystal grains of the electrodeposited copper in the wiring pattern as shown in FIG. 5(a), and in the part where cracks or disconnection occurred, re-crystallization of the electrodeposited copper was induced. Further, as shown in FIG. 5(a), in the wiring pattern which was formed in an almost straight shape and had not sharp inflection point, the bulk state (re-crystallization) of the crystal grains of the electrodeposited copper was not confirmed, and the crystal structure of the electrodeposited copper was identical to the crystal structure of the electrodeposited copper foil used.

In the wiring patterns as shown in FIGS. 5 (a) to (e), each wiring pattern was formed on the same insulating film, and using the same bonding tool, an ultrasonic wave was applied thereon so that the histories passed through the processes of the wiring patterns are identical. Accordingly, the occurrence of cracks or disconnection in the wiring pattern depends on the shape of the wiring pattern. When the edge of the wiring pattern is sharply changed, the stress caused by application with an ultrasonic wave and heating is concentrated at this inflection point in the bonding, the grain structure of the electrodeposited copper present at the inflection point is changed and the bonding strength is lowered on the interface of the bulked copper grains to cause cracks or disconnection. Therefore, when the wiring pattern is formed so as to have a shape such that the stress caused by an ultrasonic wave and heating is not concentrated in one point in bonding, it is possible to effectively prevent the wiring pattern from occurrence of cracks or disconnection. As is clear from the above results, the occurrence of cracks or disconnection is concentrated on the inflection point in the wiring pattern, and cracks or disconnection are not caused on the wiring pattern in an almost straight shape without such an inflection point. Therefore, the wiring pattern is formed at least so as to have no inflection point at which the edge of the wiring pattern is sharply changed, from the bonding spot to the solder resist layer, i.e. the wiring pattern is formed to have an approximately straight shape so that the concentration of thermal stress caused by ultrasonic wave and vibration energy from the bonding tools can be prevented.

When the edge of the wiring pattern is bended at an angle of over 5 degrees, the concentration of the stress is confirmed and further the re-crystallization of the electrodeposited copper grains is confirmed. In the case that the wiring pattern is curved at the smallest angle of over 5 degrees in the direction of the tangential line around the curved part of the wiring pattern, the concentration of the stress is confirmed.

Accordingly, in order to not cause cracks or disconnection in the film carrier tape for mounting electronic components according to the present invention, it is necessary to form the wiring pattern in an almost straight shape at least in the above-mentioned area. Even if the edge of the wiring pattern has a bended point or a curved part, it is necessary to form the wiring pattern in an almost straight shape so as to have the angles of less than 5 degrees.

The occurrence of disconnection or cracks caused by ultrasonic waves and heating from the above bonding tool was inspected on the wiring pattern 12 from the bonding spot BS to the edge 15a of the solder resist layer 15. As described above, ultrasonic waves and heat caused by the bonding tool are spread by the formed wiring pattern as a transmission means, and near the edge 15a of the solder resist layer 15, ultrasonic waves and heat act in the same way as the above. However, according to going away from the bonding point BP, the stress is decayed. On the part over 1000 μm apart from the edge 15a of the solder resist layer 15, the holding force caused by the solder resist layer and the insulating film is stronger than the stress, so that the concentration of the stress is not caused and thereby cracks or disconnection caused by bonding are not observed.

In the film carrier tape for mounting electronic components according to the present invention, the wiring pattern formed in the range 1000 μm apart from the edge 15a of the solder resist 15 has an almost straight shape, and the wiring pattern formed in this range does not have an inflection point at which the wiring pattern is sharply changed.

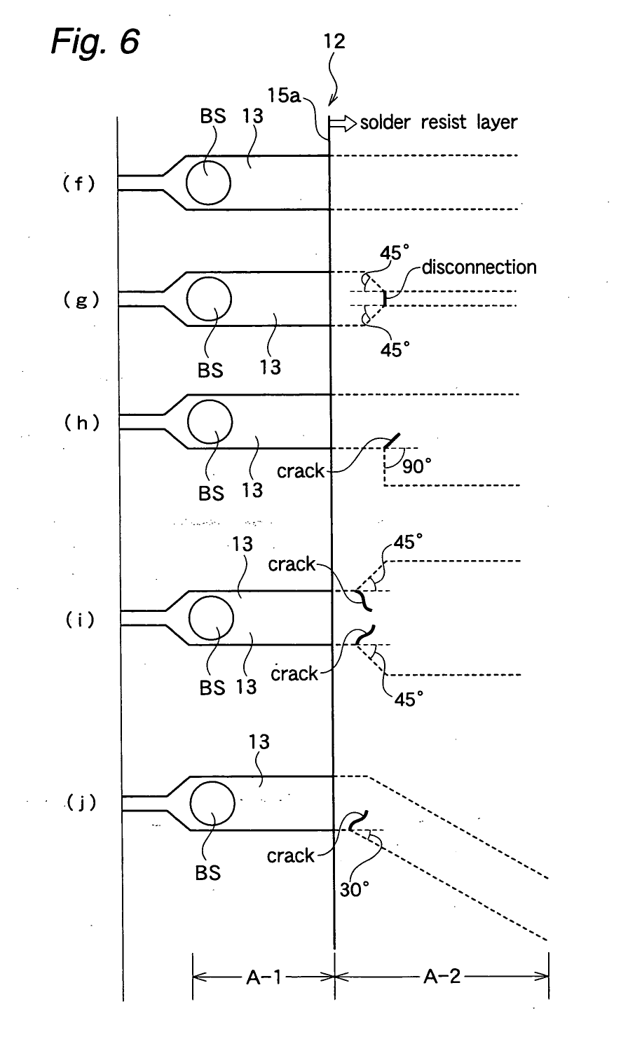

That is, in FIGS. 6 (f) to (j), the wiring patterns having the figures corresponding to FIGS. 5 (a) to (e) are formed. FIGS. 6 (g) to (j) show the embodiments that inflection points at which each wiring pattern is sharply changed are present in the wiring pattern present under the solder resist layer 15.

Using the same apparatus as in the wiring pattern shown in FIG. 5, the bonding spot BS of each wiring pattern was subjected to application of an ultrasonic wave at the maximum output [ultrasonic wave output 3.1 W, temperature 200° C.] for 0.02 sec from the bonding tool with a heating stage 40 at a heating temperature of 200° C., and thereafter the solder resist layer 15 was removed by dissolution using an organic solvent to reveal the wiring pattern present under the solder resist layer 15. With regard to the wiring pattern, the presence or absence of cracks or disconnection was examined. As a result, in the wiring pattern 12, which is formed in an almost straight shape toward the bonding pad as shown in (f), disconnection and cracks did not occur. Further, before and after the application with an ultrasonic wave on the wiring pattern, the grain texture of the electrodeposited copper was examined using an electron microscope. As a result, the change of the grain texture was not confirmed. That is, in the wiring pattern 12, which is formed in an almost straight shape, the ultrasonic wave applied on the bonding pad 13 is not concentrated on one point and acts on the whole uniformly and thermal energy is also dispersed, and thereby cracks or disconnection is not caused.

Against the wiring pattern (f), in the wiring pattern as shown in FIG. 6(g), disconnection is observed in the narrowed part. In the wiring part as shown in FIG. 6(h), the wiring pattern is bended at an about right angle in the part where the wiring pattern is spread. Cracks were occurred in this part. In each of the wiring patterns as shown FIGS. 6(i) and (j), occurrence of cracks was observed at the bended point where the wiring pattern is sharply changed.

Furthermore, the cross section of the part where cracks or disconnection have been occurred in the wiring pattern was observed by an electron microscope and then it was confirmed that similar to the above, crystal grains of the electrodeposited copper are bulked and then re-crystallized in a round state. The conditions of occurrence of cracks or disconnection are similar to those in the range where the solder resist layer 15 is not provided. In accordance with the occurrence of cracks or disconnection, cracks will frequently occur also in the solder resist layer.

The occurrence of cracks or disconnection caused by ultrasonic waves was confirmed in the range (A-2) 1000 μm from the edge 15a of the solder resist layer 15, but in the range over 1000 μm, occurrence of cracks or disconnection caused by ultrasonic wave was not confirmed.

In the above test, as an ultra sonic wave was applied on at the maximum output of the apparatus used, the occurrence of cracks or disconnection could be re-produced with a percentage of about 100%. For example, as the ultrasonic wave used in usual wire bonding using a gold wire is a ultrasonic wave having a very low output as compared with the output of the ultrasonic wave used in the above, the percentage of occurrence of cracks or disconnection is low. When a film carrier (defective product) having cracks or disconnection is observed on the grain structure of the parts where cracks or disconnection occurred using an electron microscope, similar to the above, the crystal grains of the electrodeposited copper are bulked and re-crystallized in a round state, and further the cracks or disconnection occur in the part near the inflection point where the edge of the wiring pattern is sharply changed.

Accordingly, although the percentage of occurrence of cracks or disconnection is low, the same phenomena are caused in the wiring pattern as the case that an ultrasonic wave is applied on with high output. In securing electrical connection with electric components, a wiring pattern present in the regular range from the bonding spot BS is formed in an almost straight shape and thereby occurrence of cracks and occurrence of disconnection can be prevented and further a proportion of defective products caused by these occurrences is decreased.

The wiring pattern in the film carrier tape for mounting electronic components is generally formed in consideration of the position of a bump electrode in an electronic component for mounting and the position of an external connection terminal in a film carrier. In such wiring pattern, the cause of occurrence of cracks or disconnection has not been analyzed rigidly. Therefore, in planning a wiring pattern, the wiring pattern is formed on the bases of effectively utilizing a limited space (wiring pattern forming area on an insulating film). The shape of the wiring pattern was determined without taking the probability of the occurrence of cracks or disconnection into consideration. Further, if an electrodeposited copper foil used has a certain extent thickness, there was no necessity for taking the occurrence of disconnection or cracks caused by ultrasonic waves into consideration.

However, in these later years, electrodeposited copper foils are thinned remarkably according to the demand of mounting electronic components with high density. Under the circumstances, it was revealed that even ultrasonic waves cause the occurrence of cracks or disconnection, although ultrasonic wave has been considered that it is unrelated to the occurrence of cracks or disconnection. The present invention relates to a film carrier tape for mounting electronic components having a wiring pattern which tape can prevent the occurrence of cracks or disconnection caused by such ultrasonic waves. Further, the present invention can beforehand avoid the occurrence of defects on circuits after mounting electronic components.

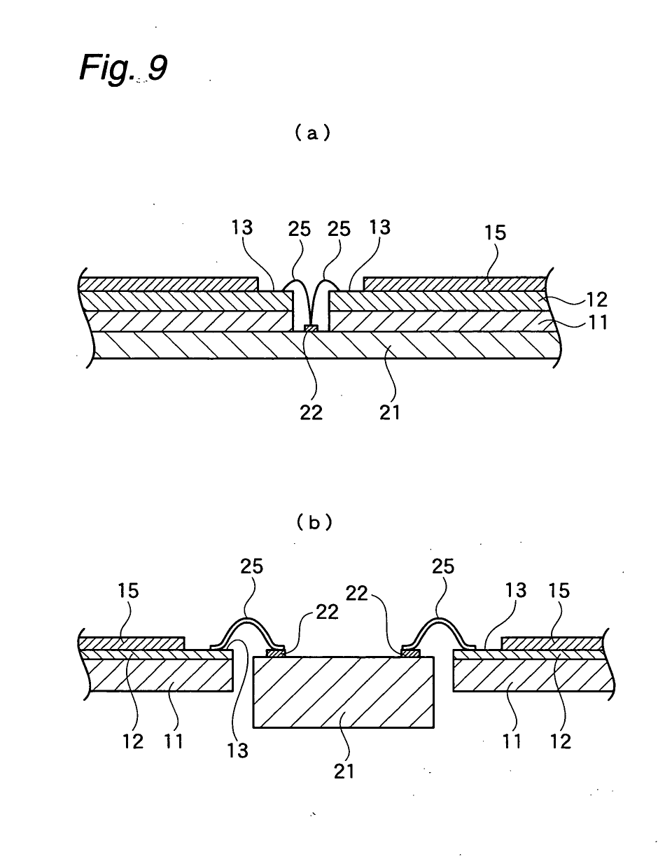

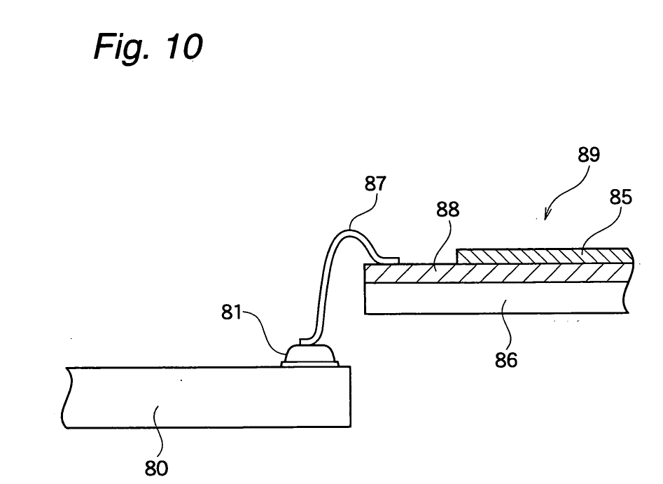

The film carrier tape for mounting electronic components according to the present invention is a type such that an electronic component 21 and a film carrier are subjected to wire bonding using a conductive metal thin wire 25 with an ultrasonic wave in the mounting the electronic component 21. The film carrier tape for mounting electronic components according to the present invention is not limited on the film carrier tapes for mounting electronic components as shown in FIG. 1 to 3. For example, FIG. 9(a) shows a film carrier tape for mounting electronic components having a structure such that a slit is formed in an insulating film 11, an electronic component 21 is set up on the surface where an wiring pattern 12 is not formed in the insulating film 11, and a bump electrode 22 positioned inside the slit is electrically connected with a bonding pad 13 by a conductive metal thin wire 25. Even in the film carrier tape for mounting electronic components, as the conductive metal thin wire 25 is fused and bonded on the bonding pad 13 using an ultrasonic wave, the same effect is successfully exhibited by forming the wiring pattern in the same manner as above.

FIG. 9 (b) shows a film carrier tape for mounting electronic components having a device hole. Even in this case, as a bump electrode 22 of an electronic component 21 is electrically connected with a bonding pad 13 by fusing and bonding a conductive metal thin wire 25 with an ultrasonic wave, the same effect is successfully exhibited by forming the wiring pattern as described above.

In the film carrier tapes for mounting electronic components as shown in FIGS. 9 (a) and (b), the same member is indicated by the same number as in FIG. 1

Furthermore, there is a film carrier tape for mounting electronic components such that an inner connection terminal is directly abutted to a bump electrode of an electronic component, and the inner connection terminal is directly connected to the bump electrode by application of an ultrasonic wave on the inner connection terminal in the mounting of the electronic component. In this case, the same effect is sufficient by forming the wiring pattern as described above.

### INDUSTRIAL UTILITY

Using the film carrier tape for mounting electronic components according to the present invention, cracks or disconnection hardly occur in a wiring pattern even if an ultrasonic wave is applied on an inner connection terminal in securing electric connection with an electronic component. In particular, even in the case of forming a wiring pattern by using a thin electrodeposited copper foil, disconnection or cracks are hardly caused in the wiring pattern.

Further, according to the present invention, cracks or the like are also hardly caused in a solder resist layer.

1. A film carrier tape for mounting electronic components, which tape comprises an insulating film and, on the surface thereof, an inner connection terminal, an outer connection terminal and a wiring for connecting these terminals and further comprises a solder resist layer covered in such a way that the connection terminals are exposed, and which tape secures electric connection of a connection terminal of an electronic component and the inner connection terminal by applying an ultrasonic wave on the inner connection terminal in mounting the electronic component,
wherein wiring positioned from a part where the inner connection terminal is electrically connected with the connection terminal of the electronic component to the edge of the solder resist layer and wiring in a 1000 μm length from the edge of the solder resist, which wiring is protected by the solder resist layer, are formed in an almost straight shape.

2. The film carrier tape for mounting electronic components according to claim 1 wherein the inner connection terminal is a bonding pad, and the connection terminal of the electronic component and the bonding pad are electrically connected by wire bonding using a conductive metal thin wire.

3. The film carrier tape for mounting electronic components according to claim 1 wherein wiring positioned from the part where the inner connection terminal is electrically connected with the connection terminal of the electronic component to the edge of the solder resist layer and wiring in a 1000 μm length from the edge of the solder resist, which wiring is protected by the solder resist layer, are formed as to not have an inflection part at which wiring is sharply bended or curved.

4. The film carrier tape for mounting electronic components according to claim 1 wherein a wiring pattern comprising the inner connection terminal, the outer connection terminal and the wiring for connecting those connection terminals is formed by selectively etching an electrodeposited copper foil and at least the crystal structure of the inner connection terminal and the crystal structure of the electrodeposited copper foil for forming the wiring have identity before and after the wire bonding.

5. The film carrier tape for mounting electronic components according to claim 4 wherein the wiring pattern is formed by selectively etching the electrodeposited copper foil having an average thickness of from 5 to 35 μm.

6. The film carrier tape for mounting electronic components according to claim 2 wherein wiring positioned from the part where the inner connection terminal is electrically connected with the connection terminal of the electronic component to the edge of the solder resist layer and wiring in a 1000 μm length from the edge of the solder resist, which wiring is protected by the solder resist layer, are formed as to not have an inflection part at which wiring is sharply bended or curved.

7. The film carrier tape for mounting electronic components according to claim 2 wherein a wiring pattern comprising the inner connection terminal, the outer connection terminal and the wiring for connecting those connection terminals is formed by selectively etching an electrodeposited copper foil and at least the crystal structure of the inner connection terminal and the crystal structure of the electrodeposited copper foil for forming the wiring have identity before and after the wire bonding.

8. The film carrier tape for mounting electronic components according to claim 7 wherein the wiring pattern is formed by selectively etching the electrodeposited copper foil having an average thickness of from 5 to 35 μm.
